(19) United States
(12) Patent Application Publication
(10) Pub. No.: US 2021/0257272 A1
(43) Pub. Date: Aug. 19, 2021

(54) CUSTOMIZED INTEGRATED HEAT SPREADER DESIGN WITH TARGETED DOPING FOR MULTI-CHIP PACKAGES

(71) Applicant: Intel Corporation, Santa Clara, CA (US)

(72) Inventors: Shrenik KOTHARI, Phoenix, AZ (US); Arivindha ANTONISWAMY, Phoenix, AZ (US)

(21) Appl. No.: 16/794,815

(22) Filed: Feb. 19, 2020

(51) Int. Cl. H01L 23/367; H01L 23/373

(52) U.S. Cl. CPC H01L 23/3672; H01L 23/3736; H01L 23/3732

(57) ABSTRACT

Embodiments include semiconductor packages. A semiconductor package includes a first die and a second die on a package substrate, and an integrated heat spreader (IHS) over the first die, the second die, and the package substrate, wherein the IHS has a lid and a plurality of sidewalls. The semiconductor package also includes a plurality of conductive slugs in the lid of the IHS. The lid of the IHS has a bottom surface that is coplanar to bottom surfaces of the conductive slugs. The conductive slugs are comprised of high-k thermal conductive materials, including cubic boron nitride, hexagonal boron nitride, graphite, carbon-based materials, diamonds, or diamond-based materials. The bottom surfaces of the conductive slugs are on a top surface of the first die and a top surface of the second die. The IHS is comprised of thermal conductive materials, including aluminum, copper, copper-based metals, or alloys.

### FIELD

Embodiments relate to packaging semiconductor devices. More particularly, the embodiments relate to semiconductor devices having customized integrated heat spreaders with targeted doping regions.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor devices. The drive to scale-down features in ICs such as multi-chip packages (MCPs), while optimizing the performance of each device, however is not without issue.

Some of the main issues involve the thermal management of such MCPs. For example, due to the increased temperature around the transistor devices, the memory devices, and other high-powered devices used in MCPs, such devices have led to substantially heightened thermal reliability and throttle risks in the MCPs. That is, high-bandwidth memory and transceiver devices have showed significant temperature increases in products (e.g., semiconductor packages, MCPs, and/or the like), which have ultimately lead to capping (or conditioning) the thermal design power capabilities of these products. Also, in these packages, embedded bridges (or bridge dies) may be used to communicatively couple dies, however the bridges have encountered substantially increased thermal cross talk between the main dies and the satellite dies (or peripheral dies), which has ultimately lead to compromises and limitations in both the performance of the satellite dies and the main dies.

Accordingly, one existing packaging solution (or mitigating procedure) may involve reducing of the current (e.g., Lc), the bandwidth, and the respective total power, which leads to lower frequency specifications and lower bandwidth performances. Another existing packaging solution may involve employing complicated designs/components, cost-intensive packaging technologies, and/or complicated, uncertain, and cost-intensive thermal solutions (e.g., integrated heat spreaders (IHSs)). For example, the existing IHS packaging solutions have encountered several challenges in maintaining the mechanical integrity of the MCP, showed assembly challenges in maintaining the optimum thickness of the thermal interface materials (or sealant materials) used in the MCPs, and/or been limited to specific products (or customers) due to the complicated designs, increased costs, and/or uncertainty of such IHSs.

### BRIEF DESCRIPTION OF THE DRAWINGS

Embodiments described herein illustrated by way of example and not limitation in the figures of the accompanying drawings, in which like references indicate similar features. Furthermore, some conventional details have been omitted so as not to obscure from the inventive concepts described herein.

FIG. 1 is an illustration of a cross-sectional view of a semiconductor package with an integrated heat spreader (IHS), a plurality conductive regions, a plurality of dies, and a package substrate, according to one embodiment.

FIG. 2 is an illustration of a cross-sectional view of a semiconductor package with an IHS, a plurality conductive regions, a plurality of dies, and a package substrate, according to one embodiment.

FIG. 3A is an illustration of a cross-sectional view of a semiconductor package with an IHS, a plurality conductive regions, a plurality of dies, and a package substrate, according to one embodiment.

FIGS. 3B-3D are illustrations of plan views of a plurality of conductive regions having one or more different shapes, according to one embodiment.

FIG. 4 is an illustration of a cross-sectional view of a semiconductor package with an IHS, a thermal interface material (TIM), a plurality conductive regions, a plurality of dies, and a package substrate, according to one embodiment.

FIG. 5 is an illustration of a cross-sectional view of a semiconductor package with an IHS, a plurality conductive regions, a plurality of top dies, a plurality of bottom dies, a die, an encapsulation layer, and a package substrate, according to one embodiment.

FIG. 6 is an illustration of a cross-sectional view of a semiconductor package with a heatsink, a TIM, an IHS, a plurality conductive regions, a plurality of dies, a package substrate, and a substrate, according to one embodiment.

FIG. 7 is an illustration of a schematic block diagram illustrating a computer system that utilizes a semiconductor package with an IHS, a plurality conductive regions, a plurality of dies, and a package substrate, according to one embodiment.

### DETAILED DESCRIPTION

Described herein are semiconductor packages having customized integrated heat spreaders with targeted doping regions and methods of forming such semiconductor packages. The semiconductor packages described below and methods of forming such semiconductor packages may include a heatsink, a thermal interface material (TIM), an integrated heat spreader (IHS), a plurality of conductive slugs (or thermally conductive slugs), a plurality of dies, an encapsulation layer, a package substrate, and a substrate.

In the embodiments described herein, the semiconductor package may have the dies disposed on the package substrate, and the IHS disposed over the dies and the package substrate, where the IHS may be implemented (or designed/shaped) with a lid and a plurality of sidewalls (or posts). Additionally, in these embodiments, the semiconductor package may have the conductive slugs disposed in the lid of the IHS, where the lid of the IHS may have a bottom surface that is substantially coplanar to the bottom surfaces of the conductive slugs, and where the bottom surfaces of the conductive slugs may be positioned over/on the top surfaces of the dies. In these embodiments, the conductive slugs may be positioned over the dies and disposed in a lid of the IHS. For example, the conductive slugs may be implemented as targeted doped regions in the lid of the IHS, where the targeted doped regions may be comprised of high-k thermally conductive materials, low-k thermally conductive materials, or the like, according to some embodiments.

As described herein, a “conductive slug” may refer to a region (or a targeted doped region) or an insert (or a targeted doped insert) comprised of high-k thermally conductive materials (e.g., boron nitride (BN), diamond, or the like), low-k thermally conductive materials (e.g., epoxy or the like), or the like, where one or more regions (or inserts) may be directly disposed and selectively positioned in the lid of the IHS. Accordingly, the bottom surfaces of the selectively positioned regions may thus be thermally coupled to the top surfaces of the dies to improve the overall thermal design power (TDP) capabilities of the semiconductor package by (i) reducing the overall thermal energy (or heat) generated by the dies, (ii) reducing the thermal resistance between the lid of the IHS and the dies, (iii) enhancing heat spread from the active die regions to the passive regions, and (iv) reducing the adverse cross-talk generated by the dies (e.g., the embedded bridge dies or the like). In particular, according to some embodiments, the conductive slug described herein may be implemented as targeted doped regions in the lid of the IHS, where the targeted doped regions may have one or more different shapes based on the respective shapes and positions (or locations) of the respective dies. In these embodiments, the conductive slugs described herein may have bottom surfaces substantially coplanar to the bottom surface of the lid of the IHS, where the bottom surfaces of the conductive slugs may be directly coupled to and positioned on the top surfaces of the dies without a TIM layer in between the respective conductive slugs and dies.

The embodiments of the semiconductor packages described herein provide improvements to existing packaging solutions by substantially reducing the maximum die temperatures, and increasing the thermal design power (TDP) capabilities of the semiconductor packages described herein. These improvements are due to the extremely good heat spreading capabilities of the embodiments of the conductive slugs as well as reducing the thermal path (or the thermal interface) between the dies and the IHS (e.g., the TIM typically disposed between the top surfaces of the dies and the bottom surface of the lid of the IHS may be removed (if desired)).

Additionally, in these embodiments, the conductive slugs described herein improve the existing packaging solutions by providing targeted doped regions (or strategic placement of thermal conductive materials) in the lid of the IHS. As such, one or more of the conductive slugs (or doped regions) may be comprised of one or more high-k conductive materials such as cubic BN, diamond, or the like, where such high-k conductive materials help the heat spread from local active dies (or devices) to the surrounding passive regions of the IHS. For example, the conductive slugs may be comprised of high-k BN materials that may address and reduce the thermal energy (or heat) of the high power main dies (e.g., a processor, a high-bandwidth memory (HBM), a central processing unit (CPU), etc.). Additionally, in another example, the conductive slugs may be comprised of high-k diamond materials that may address and reduce the thermal energy on the periphery regions (or the edges) of the top surfaces of the main dies and/or the satellite dies (i.e., the satellite dies may be disposed and positioned on the periphery region(s) of the top surface of the package substrate, where such satellite dies may also be positioned adjacent to the main dies that are more centrally disposed and positioned on the top surface of the package substrate).

Also, in some examples, the high-k thermal conductive materials of the conductive slugs may be implemented as hexagonal BN regions (or the like) that may respectively introduce anisotropy with such thermal k properties (i.e., the hexagonal BN regions may be used to direct the heat in a specified path/direction). Meanwhile, in other embodiments, the conductive slugs may be comprised of low-k polymer materials (e.g., epoxy or the like) that address and reduce the adverse cross-talk across the embedded bridge dies. Lastly, in some embodiments, the IHS may be comprised of one or more conductive materials such as sintered aluminum (or the like) that surrounds the conductive slugs and thus further addresses and reduces the lateral cross-talk generated by the main dies, the satellite dies, and/or the embedded bridge dies.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, interne devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages with heatsinks, TIMs, IHSs, conductive slugs, encapsulation layers, dies, embedded bridges, package substrates, and substrates.

In the following description, various aspects of the illustrative implementations will be described using terms commonly employed by those skilled in the art to convey the substance of their work to others skilled in the art. However, it will be apparent to those skilled in the art that the present embodiments may be practiced with only some of the described aspects. For purposes of explanation, specific numbers, materials and configurations are set forth in order to provide a thorough understanding of the illustrative implementations. However, it will be apparent to one skilled in the art that the present embodiments may be practiced without the specific details. In other instances, well-known features are omitted or simplified in order not to obscure the illustrative implementations.

Various operations will be described as multiple discrete operations, in turn, in a manner that is most helpful in understanding the present embodiments, however, the order of description should not be construed to imply that these operations are necessarily order dependent. In particular, these operations need not be performed in the order of presentation.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

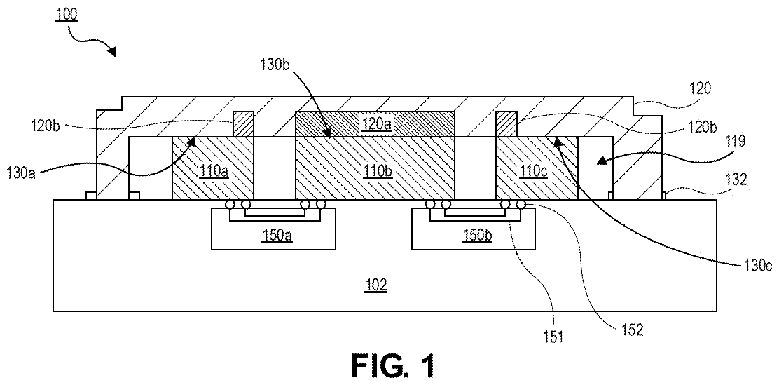

Referring now to FIG. 1, a cross-sectional illustration of a semiconductor package 100 is shown, in accordance with an embodiment. For some embodiments, the semiconductor package 100 may include an IHS 120, a plurality of conductive slugs 120a-b, a plurality of interfaces 130a-c, a plurality of dies 110a-c, a package substrate 102, a plurality of bridges 150a-b, and a sealant 132, according to one embodiment. In one embodiment, the dies 110a-c (or the first, second, and third dies) may be disposed on the top surface of the package substrate 102. For one embodiment, the dies 110a-c may be conductively coupled to the package substrate 102. Additionally, in other embodiments, the dies 110a-c may be communicatively coupled to each other with the bridges 150a-b (or the bridge dies).

In an embodiment, the IHS 120 may be coupled to the top surface of the package substrate 102 with the sealant 132 (or an adhesive layer or the like), where the IHS 120 may be implemented (or designed/shaped) with a lid and a plurality of sidewalls. For one embodiment, the lid and the sidewalls of the IHS 120 may form a cavity 119 over the top surface of the package substrate 102 and surrounding the dies 110a-c. Additionally, in these embodiments, the conductive slugs 120a-b may be disposed (or inserted/formed) in the lid of the IHS 120, where the lid of the IHS 120 may have a bottom surface that is substantially coplanar to the bottom surfaces of the conductive slugs 120a-b.

As shown in FIG. 1, the conductive slugs 120a-b may be selectively positioned in the lid of the IHS 120 and over/on the respective dies 110a-c. In particular, the bottom surfaces of the conductive slugs 120a-b may be positioned directly over/on portions (or regions) of the top surfaces of the dies 110a-c, where the conductive slugs 120a-b may substantially bond (or attach) to the dies 110a-c at the interfaces 130a-c (or the barriers) directly between the respective conductive slugs 120a-b and dies 110a-c. That is, in some embodiments, the conductive slugs 120a-b may cover a partial portion or an entire portion of the top surfaces of the dies 110a-c. For example, the conductive slugs 120b may be disposed on the periphery regions (or the outer regions) of the top surfaces of the dies 110a and 110c (or the satellite dies), while the conductive slug 120a may be disposed approximately on the center region (or the inner region) of the top surface of the die 110b (or the main die).

In these embodiments, the conductive slugs 120b may be disposed on any of the periphery regions of the top surface of the dies 110a and 110c. For example, one of the conductive slugs 120b may be disposed on the outer periphery region of the top surface of the die 110a (i.e., the farthest left region of the top surface of the die 110a that is closest to the left sidewall of the IHS 120), while the other one or more of the conductive slugs 120b may be disposed on the inner periphery region of the top surface of the die 110c (as shown in FIG. 1).

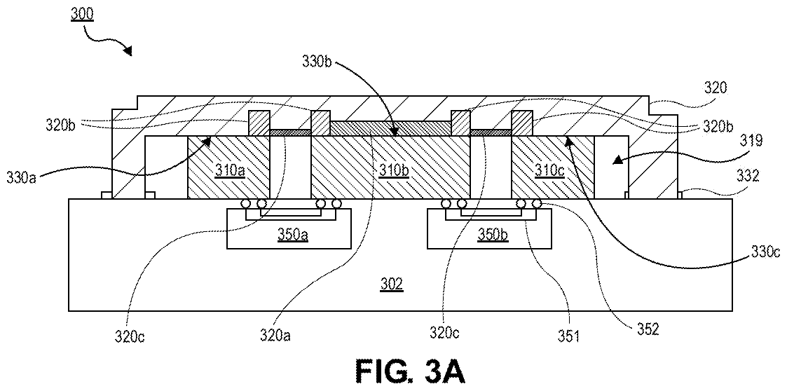

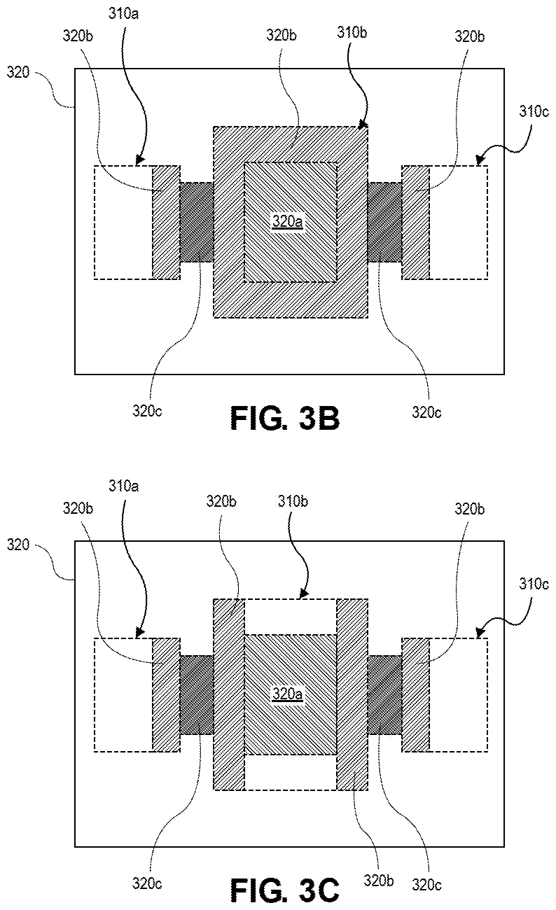

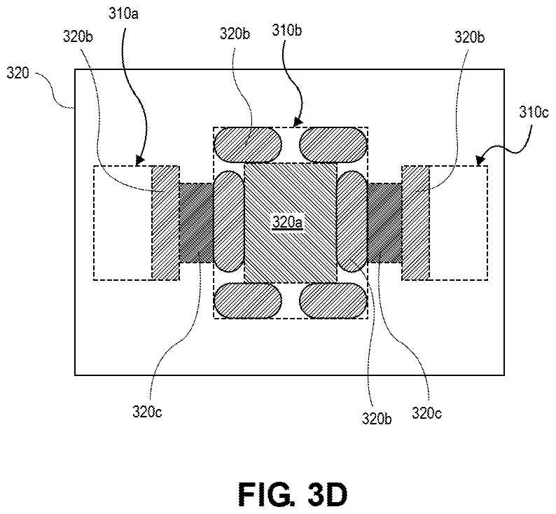

Note that, in other embodiments, one or more of the conductive slugs 120b may be disposed on one or more of the outer periphery regions of the top surface of one or more of the dies 110a and 110c, where the conductive slugs 120b may be on one periphery region, two periphery regions, and so on. For example, as shown in FIG. 3B, one of the conductive slugs 320b may be disposed on one periphery region of the top surface of the die 310a, and may be shaped as a line, a trace, or the like; likewise, as shown in FIG. 3B, another of the conductive slugs 320b may be disposed on the periphery regions of the top surface of the die 310b, and may be shaped as a picture frame or the like. Also note that, in some embodiments, the conductive slugs 120b may be a plurality of smaller conductive slugs (or smaller portions) disposed on one or more periphery portions (or regions) of the top surfaces of one or more of the dies 110a-c, where the smaller conductive slugs may be selectively positioned to implement (or form/shape) a larger conductive slug. For example, as shown in FIG. 3D, the smaller conductive slugs 320b may be disposed on the periphery portions of the top surface of the die 310b, where the smaller conductive slugs 320b may be spaced apart from each other (e.g., as small dashed lines with rounded and/or sharp edges), and separated from the other smaller conductive slugs with the thermal conductive portions of the lid of the IHS 320 (e.g., the thermal conductive portions of the lid of the IHS 320 may be comprised of sintered aluminum or the like).

In these embodiments, the conductive slugs 120a-b may be implemented as a plurality of targeted regions or a plurality of targeted inserts in the lid of the IHS 120, where the targeted regions/inserts may be doped with (or comprised of) high-k thermally conductive materials (e.g., BN, diamond, or the like), low-k thermally conductive materials (e.g., epoxy or the like), or the like. These conductive slugs 120a-b may be selectively positioned in the lid of the IHS 120 and directly on/over the respective dies 110a-c, where the conductive slugs 120a-b may be thermally coupled to the top surfaces of the respective dies 110a-c to improve the overall TDP capabilities of the semiconductor package 100.

Furthermore, in some embodiments, the bridges 150a-b may be disposed (or embedded) in the package substrate 102, and the bridges 150a-b may communicatively couple the dies 110a-c to each other. In an embodiment, the bridges 150a-b may comprise electrical routings 151-152 (or interconnect structures) to communicatively couple the dies 110a-c to each other. In an embodiment, the bridges 150a-b may be a silicon bridge, a glass bridge, or a bridge made of any other substrate material that is suitable for forming bridges. In some embodiments, the bridges 150a-b may be referred to as an embedded multi-die interconnect bridge (EMIB). For additional embodiments, the bridges 150a-b may include TSVs 151 (or the like) that may be used to communicatively couple the dies 110a-c.

Note that, according to some embodiment, the semiconductor package 100 is merely one example of an embodiment of a semiconductor packaged system. That is, the semiconductor package 100 is not limited to the illustrated semiconductor packaged system, and thus may be designed/formed with fewer, alternate, or additional packaging components and/or with different interconnecting structures. For example, while one IHS 120, three conductive slugs 120a-b, three dies 110a-c, and one package substrate 102 with two bridges 150a-b are illustrated, it is to be appreciated that the semiconductor package 100 may include any number of IHSs 120, conductive slugs 120a-b, dies 110a-c, and package substrates 102 with bridges 150a-b.

For one embodiment, the semiconductor package 100 may include a ball grid array (BGA) package, a land grid array (LGA) package, and/or a pin grid array (PGA) package. In other embodiments, one or more of the dies 110a-c and/or the package substrate 102 may be coupled via solder balls, such as the solder balls 152, which may be implemented as solder bumps/joints formed from respective microbumps. A solder ball (or joint) formed by soldering of a microbump according to an embodiment may itself be referred to as a “bump” and/or a “microbump.” Additionally, for other embodiments, one or more of the dies 110a-c and the package substrate 102 may be coupled using an anisotropic conductive film (ACF) or the like.

The package substrate 102 may include a variety of electronic structures formed thereon or therein. In certain embodiments, the package substrate 102 may be an organic substrate made up of one or more layers of polymer base materials or ceramic base materials, with conducting regions for transmitting signals. For some embodiments, the package substrate 102 may include, but is not limited to, a package, a substrate, a printed circuit board (PCB), and a motherboard. In one embodiment, the package substrate 102 is a PCB. For one embodiment, the PCB is made of an FR-4 glass epoxy base with thin copper foil laminated on both sides. For certain embodiments, a multilayer PCB can be used, with pre-preg and copper foil used to make additional layers. For example, the multilayer PCB may include one or more dielectric layers, where the dielectric layers may be a photosensitive dielectric layer. For one embodiment, the PCB 102 may also include one or more conductive layers, which may further include copper (or metallic) traces, lines, pads, vias, holes, and/or planes.

For one embodiment, the dies 110a-c may be comprised, but are not limited to, a semiconductor die, an electronic device (e.g., a wireless device), an integrated circuit (IC), a central processing unit (CPU), a graphic processing unit (GPU), a microprocessor, a platform controller hub (PCH), a memory (e.g., a HBM), and/or a field-programmable gate array (FPGA). Additionally, in other embodiments, the dies 110a-c may be comprised of one or more materials, including glass, crystal, diamond, low thermal conductive materials, high thermal conductive materials (e.g., gallium nitride (GaN) or the like), silicon, glass-based materials, and/or silicon-based materials (e.g., silicon carbide (SiC) or the like).

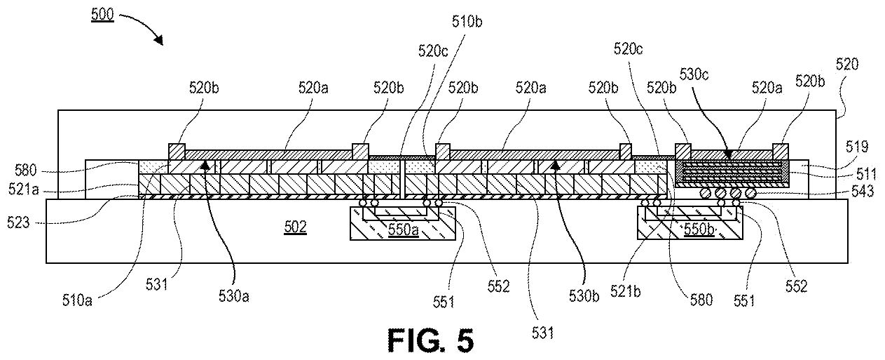

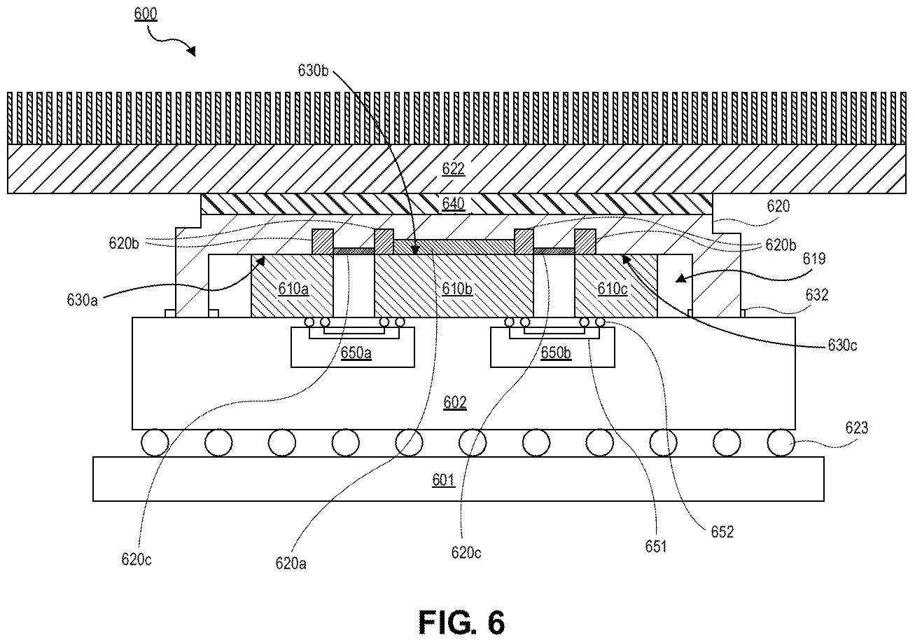

In some embodiments, the die 110b may be implemented as a high power main die that may be centrally positioned below the lid of the IHS 120, while the dies 110a and 110c may be implemented as a satellite die that may be peripherally positioned below the lid of the IHS 120. In other embodiments, the dies 110a-c may be a plurality of chiplet dies (or the like). While, in another embodiment, the dies 110a-c may be implemented as a stack of dies (e.g., a plurality of chiplet dies (or a top die) stacked on a die (or a bottom die) as shown in FIG. 5). The dies 110a-c may be formed from a material such as silicon and have circuitry thereon that is to be coupled to the package substrate 102 and/or each other. Although some embodiments are not limited in this regard, the package substrate 102 may in turn be coupled to another body, for example, a computer motherboard or the like (e.g., as shown with the package substrate 602 and the substrate 601 in FIG. 6).

For one embodiment, the dies 110a-c may have a thickness that is substantially equal to each other. As such, in these embodiments, each of the dies 110a-c may have a top surface that is substantially coplanar to a top surface of the other dies 110a-c. For one embodiment, the dies 110a-c may have a thickness of approximately 100 um or less. In other embodiments, the dies 110a-c may have a thickness of approximately 100 um to 600 um. Also, in alternative embodiments, one or more of the dies 110a-c may have a thickness that is different from a thickness of the other one or more dies 110a-c. Note that, in these alternative embodiments (i.e., when one or more of the dies 110a-c have different/varying thicknesses), a TIM (or the like) may be disposed on the respective die that has the lower thickness and may be used to offset (or level out) the thickness of the respective die, where the thickness of the TIM may be adjusted to any desired thickness to allow the stacked TIM and respective die to have a thickness that is substantially equal to the thickness of the other dies.

One or more connections between the package substrate 102, the dies 110a-c, and the bridges 150a-b may include one or more interconnect structures and underfill layers if desired. In some embodiments, these interconnect structures (or connections) may variously comprise an alloy of nickel, palladium, and tin (and, in some embodiments, copper). For one embodiment, the underfill layers may be one or more polymer materials that are injected between the respective components. Alternatively, the underfill layers may be molded underfills (MUF) or the like.

As described above, the conductive slugs 120a-b may be disposed (or embedded) in the lid of the IHS 120. The conductive slugs 120a-b may be positioned over the respective dies 110a-c at the respective interfaces 130a-c. In one embodiment, the conductive slug 120b may be disposed on a portion of the top surface of the first die 110a (or the satellite die) at the first interface 130a (e.g., disposed on a periphery portion of the top surface of the first die 110a). In another embodiment, the conductive slug 120a may be disposed on the top surface of the second die 110b (or the main die) at the second interface 130b, where the bottom surface of the conductive slug 120a may substantially cover the top surface of the second die 110b (e.g., the footprint (or the surface area) of the conductive slug 120a may be substantially equal to the footprint of the first die 110a). For one embodiment, the conductive slug 120b may be disposed on a portion of the top surface of the third die 110c (or the satellite die) at the third interface 130c (e.g., disposed on a periphery portion of the top surface of the third die 110c).

Accordingly, (i) the conductive slugs 120a-b may be implemented (or used) to reduce the overall thermal energy (or heat) generated by the dies 110a-c, (ii) to reduce the thermal resistance between the dies 110a-c and the lid of the IHS 120, (iii) to improve (or enhance) the heat spreading from the active die regions to the passive regions of the lid of the IHS 120, and (iv) to reduce the adverse cross-talk generated by the bridges 150a-b (or any other of the dies if desired).

According to some embodiments, the conductive slug 120a-b may be designed to have the same shape, while, in other embodiments, the conductive slugs 120a-b may be designed with one or more different shapes including squares, rectangles (e.g., lines, traces, or the like), cylinders, triangular, spherical, trapezoidal, and/or the like. In some embodiments, the conductive slugs 120a-b may have one or more sidewalls, where the sidewalls of the conductive slugs 120a-b may be shaped as tapered sidewalls, substantially vertical sidewalls, and/or rounded sidewalls. In some embodiments, the conductive slugs 120a-b may be comprised of one or more high-k thermal conductive materials and/or any similar thermal conductive materials.

In these embodiments, as shown in FIG. 1, the conductive slug 120a may be comprised of a high-k thermal conductive material that centrally addresses the thermal energy (or heat) of the die 110b, where the high-k thermal conductive material of the conductive slug 120a may be comprised of cubic BN, hexagonal BN, graphite, carbon-based materials (or solutions), and/or any other conductive material having a thermal conductivity of approximately 400 W/mK to 600 W/mK (or greater if desired). Meanwhile, in these embodiments, the conductive slugs 120b may be a high-k thermal conductive material that peripherally addresses the thermal energy of the dies 110a and 110c (e.g., the conductive slugs 120b may be positioned to address more localized hotspots on the top surfaces of the dies 110a and 110c), where the high-k thermal conductive material of the conductive slug 120b may be comprised of diamond-based materials and/or any other conductive material having a thermal conductivity of approximately 400 W/mK to 1000 W/mK (or greater if desired).

Note that, in these embodiments, the conductive slugs 120a-b may include one or more high-k thermal conductive materials, such as elements that include hafnium, silicon, gold, silver, silicon carbide, titanium, tantalum, lanthanum, aluminum, zirconium, barium, strontium, yttrium, lead, scandium, niobium, and/or zinc. As described herein, a “high-k” material (or thermal conductive material) refers to a material having a higher thermal conductivity (k) than silicon oxide, where the terms “oxide,” “carbide,” “nitride,” etc. refer to compounds containing, respectively, oxygen, carbon, nitrogen, etc. Examples of high-k materials that may be implemented for the conductive slugs 120a-b may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and/or lead zinc niobate.

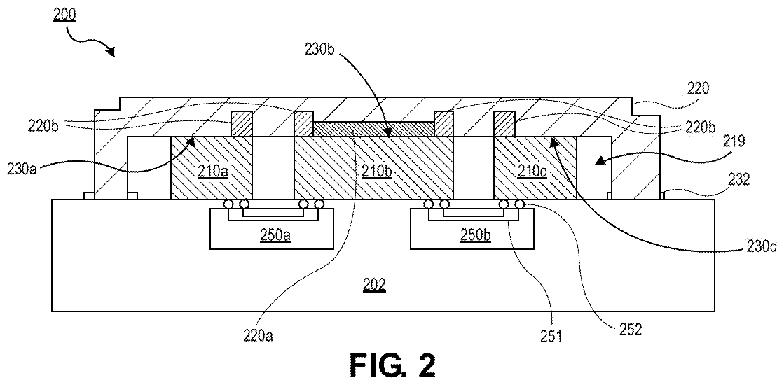

In these embodiments, the conductive slug 120a may have a thickness that is substantially equally to a thickness of the conductive slugs 120b. In other embodiments, the conductive slug 120a may have a thickness that is different than a thickness of one or more of the conductive slugs 120b (e.g., as shown with the conductive slugs 220a-b in FIG. 2). In one embodiment, the conductive slugs 120a-b may have a thickness of approximately 0.5 mm to 2 mm. For one embodiment, as shown in FIG. 1, the conductive slug 120a may have a width greater than a width of one or more of the conductive slugs 120b, where the width of the conductive slug 120a may be equal to the width of the die 110b. Note that, in some embodiments, the width of the conductive slug 120a may be slightly greater or less than the width of the die 110b (e.g., one or more of the sidewalls of the conductive slug 120a may extend over one or more of the sidewalls of the die 110b. Also note that, in some embodiments, the conductive slug 120a may have a footprint (or a surface (x-y) area) equal to or different from a footprint of the die 110b (e.g., as shown with the footprint of the conductive slug 220a that is less than the footprint of the die 210b in FIG. 2). Meanwhile, in one embodiment, the conductive slug 120b may have a width of approximately/equal to or less than 1 mm.

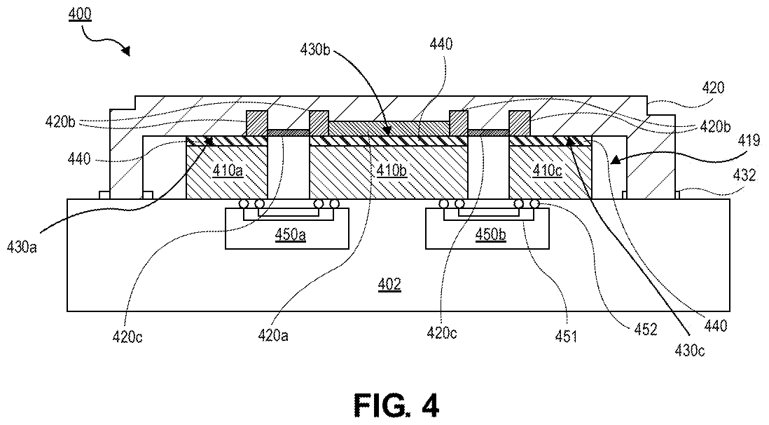

In some embodiments, the bottom surfaces of the conductive slugs 120a-b may be directly coupled to and positioned on the top surfaces of the dies 110a-c at the respective interfaces 130a-c—without a TIM (or a TIM layer or the like) in between the respective conductive slugs 120a-b and dies 110a-c. Alternatively, in other embodiments, the interfaces 130a-c may have a TIM, an adhesive, a thermal conductive layer, and/or the like (e.g., as shown in FIG. 4 with the TIM 440 located at the interfaces 430a-c and disposed between the respective conductive slugs 420a-c and dies 410a-c).

In these alternative embodiments, a TIM (or the like) may be directly disposed and coupled onto the top surfaces of the dies 110a-b, the bottom surface of the lid of the IHS 120, and the bottom surfaces of the conductive slugs 120a-b, where the TIM may be positioned between the IHS 120 and one or more of the dies 110a-c. In one embodiment, the TIM may be a solder TIM (STIM) such as an indium STIM or the like. In other embodiments, the TIM may include one or more highly thermal conductivity materials such as a metallic TIM, a STIM, a polymer (PTIM), and/or any similar highly thermal conductive material(s).

Lastly, as shown in FIG. 1, the IHS 120 may be disposed over the dies 110a-c and the package substrate 102, where the sealant 132 (or an adhesive (or the like)) may be used to couple the bottom ends of the sidewalls of the IHS 120 to the top surface of the package substrate 102. For some embodiments, the lid of the IHS 120 may have a thickness of approximately 1 mm to 3 mm, where the thickness of the conductive slugs 120a-b may be approximately 30% (or +/−20%) of the thickness of the lid of the IHS 120. Moreover, in some embodiments, the conductive material of the IHS 120 may have a thermal conductivity of approximately 100 W/mK to 250 W/mK (or greater if desired). As such, the thermal conductivity of the IHS 120 may be less than the thermal conductivity of the conductive slugs 120a-b, according to some embodiments.

In some embodiments, the IHS 120 may be a heatsink, a heat spreader, a heat exchanger, a manifold, a cold plate, and/or any similar thermal solution (or device) that may be used to help transfer the heat from the electrical components of the semiconductor package 100 to the ambient environment (or an additional heat spreader). In some embodiments, the IHS 120 may be a shared heatsink disposed over all of the dies 110a-c, or the IHS 120 may be a split heatsink separated into separate heatsinks individually disposed over each of the dies 110a-c solely.

Additionally, in some embodiments, the IHS 120 may be comprised of one or more highly thermal conductive materials such as sintered aluminum, sintered metals (e.g., copper), sintered metal alloys, and/or any other similar conductive/metal materials. For example, in these embodiments of FIG. 1, the conductive material of the lid of the IHS 120 may be used to surround (and/or embed) the conductive slugs 120a-b, where the conductive material of the lid of the IHS 120 may be sintered aluminum that surrounds, for example, the top surfaces and the outer sidewalls of the conductive slugs 120a-b. In these embodiments, the conductive slugs 120a-b may be implemented into (or in/on) the lid of the IHS 120 using one or more processes such as lithographical plating (or printing), three-dimensional (3D) printing, molding, pick and place, or the like.

As described above, in one alternative embodiment, the IHS 120 is a heatsink, for example, the heatsink 120 may be similar to the heatsink 622 described below in FIG. 6. Accordingly, in these alternative embodiments, the semiconductor package 100 omits an IHS or a heat spreader, and instead implements the heatsink 120, where the heatsink 120 may be designed substantially similar to the heatsink 622 shown in FIG. 6. That is, in these alternative embodiments, the conductive slugs 120a-b may be disposed directly into the heatsink 120, while the conductive slugs 120a-b maintain the same configuration (i.e., the same shapes, materials, positions, and so on) over the respective dies 110a-c. Accordingly, in such alternative embodiments, the bottom surfaces of the heatsink 120 and conductive slugs 120a-b may be directly disposed on the top surfaces of the respective dies 110a-c—without having an IHS and a TIM positioned between the heatsink 120 and the dies110a-c (i.e., the semiconductor package 100 is designed having the heatsink 120 with the conductive slugs 120a-b disposed directly on the bare top surfaces of the die 110a-c (without the heat spreader)).

Note that the semiconductor package 100 may include fewer or additional packaging components based on the desired packaging design.

Referring now to FIG. 2, a cross-sectional illustration of a semiconductor package 200 is shown, in accordance with an embodiment. In some embodiments, the semiconductor package 200 may be substantially similar to the semiconductor package 100 described above in FIG. 1, with the exception that each of the conductive slugs 220b may be disposed on one or more regions of the top surface of the respective dies 210a-c, and that both the conductive slugs 220a-b may be disposed on the top surface of the die 210b (or the second die, the main die, etc.).

Whereas the footprint of the conductive slug 120a shown in FIG. 1 has substantially the same footprint of the die 110b, the footprint of the conductive slug 220a shown in FIG. 2 is lower than the footprint of the die 210b. That is, in these embodiments, the conductive slug 220b may be disposed on the periphery regions of the top surface of the die 210b, while the conductive slug 220a may be disposed on the central region of the top surface of the die 210b. Accordingly, in these embodiments, the conductive slug 220b may fully and/or partially surround the conductive slug 220a, where, for example, the conductive slug 220b may be shaped as a picture frame surrounding the conductive slug 220a (e.g., as shown in FIGS. 3B and 3D with the conductive slug 320b that is shaped as a picture frame and surrounds the conductive slug 320a). Note that, in some embodiments, the conductive slugs 220b may have one or more different shapes including squares, rectangles (e.g., lines, traces, or the like), cylinders, triangular, spherical, trapezoidal, and/or the like.

Additionally, as shown in FIG. 2, the thicknesses of the conductive slugs 220b may be greater than the thickness of the conductive slug 220a. While, in another embodiment, the thicknesses of the conductive slugs 220b may be substantially equal to the thickness of the conductive slug 220a. For some embodiments, the conductive slug 220a may have a thickness that is approximately 30% to 100% (or substantially equal to) of the thickness of the conductive slugs 220b.

Likewise, the components of the semiconductor package 200 may be substantially similar to the components of the semiconductor package 100 described above in FIG. 1. Accordingly, the IHS 220, the cavity 219, the conductive slugs 220a-b, the interfaces 230a-c, the dies 210a-c, the package substrate 202, the bridges 250a-b with electrical routings 251-252, and the sealant 232 may be substantially similar to the IHS 120, the cavity 119, the conductive slugs 120a-b, the interfaces 130a-c, the dies 110a-c, the package substrate 102, the bridges 150a-b with electrical routings 151-152, and the sealant 132 described above in FIG. 1.

Note that the semiconductor package 200 may include fewer or additional packaging components based on the desired packaging design.

Referring now to FIG. 3A, a cross-sectional illustration of a semiconductor package 300 is shown, in accordance with an embodiment. In some embodiments, the semiconductor package 300 may be substantially similar to the semiconductor packages 100 and 200 described above in FIGS. 1-2, with the exception that a plurality of conductive slugs 320c may be disposed between the conductive slugs 320b and may be positioned above (or over) the bridges 350a-b.

Whereas two different conductive slugs 220a-b are shown in FIG. 2, three different conductive slugs 320a-c are shown in FIG. 3. That is, in these embodiments, the conductive slugs 320c may be disposed between the conductive slugs 320b that are disposed in the IHS 320, where the conductive slugs 320c may be positioned above (or over) the bridges 350a-b that are embedded in the package substrate 302. For example, the sidewalls of the conductive slugs 320c may be directly adjacent to the sidewalls of the conductive slugs 320b, where the bottom surfaces of the conductive slugs 320c may be disposed over the top surface of the package substrate 302, but may not overlap (or cover) the top surfaces of the dies 310a-c, according to some embodiments.

Moreover, the conductive slugs 320b may surround one or more of the sidewalls of the conductive slugs 320c. In these embodiments, as shown in FIG. 3A, the thicknesses of the conductive slugs 320b may be greater than the thicknesses of the conductive slugs 320a and 320c, additionally the thickness of the conductive slug 320a may be greater than the thicknesses of the conductive slugs 320c. While, in another embodiment, the thicknesses of the conductive slugs 320b may be substantially equal to the thickness of one or more of the conductive slugs 320a and/or 320c. That is, in these other embodiments, the thicknesses of the conductive slugs 320b may be substantially equal to the thickness of the conductive slug 320a or the thickness of one or more of the conductive slugs 320c. In some embodiments, the conductive slugs 320a and/or 320c may have a thickness that is approximately 30% to 100% (or substantially equal to) of the thickness of the conductive slugs 320b.

In these embodiments, the conductive slugs 320c may be comprised of a low-k thermally conductive material that helps to reduce (or minimize) the cross-talk across the bridges 350a-b, where the low-k thermally conductive material of the conductive slugs 320c may be comprised of epoxies, polymers, metals, alloys, and/or any other low-k conductive material having a thermal conductivity that is approximately equal to or less than 30 W/mK. As described herein, a “low-k” material (or thermally conductive material) refers to a material having a lower thermal conductivity (k) than silicon oxide, where the terms “oxide,” “carbide,” “nitride,” etc. refer to compounds containing, respectively, oxygen, carbon, nitrogen, etc. Examples of low-k materials of the conductive slugs 320c may include, but are not limited to, carbon-doped oxide, porous silicon dioxide, organic polymers such as perfluorocyclobutane, polytetrafluoroethylene, fluorosilicate glass, and/or organiosilicates, such as silsesquioxane, siloxane, or organosilicate glass, and/or polymers such as polyimide, polynorbornenes, benzocyclobutene, PTFE, and/or a combination of the above materials with modified structures.

Additionally, the components of the semiconductor package 300 may be substantially similar to the components of the semiconductor package 200 described above in FIG. 2. Accordingly, the IHS 320, the cavity 319, the conductive slugs 320a-c, the interfaces 330a-c, the dies 310a-c, the package substrate 302, the bridges 350a-b with electrical routings 351-352, and the sealant 332 may be substantially similar to the IHS 220, the cavity 219, the conductive slugs 220a-b, the interfaces 230a-c, the dies 210a-c, the package substrate 202, the bridges 250a-b with electrical routings 251-252, and the sealant 232 described above in FIG. 2.

Referring now to FIGS. 3B-3D, several plan view illustrations of one or more different shapes of the respective conductive slugs 320b and IHS 320 are shown, in accordance with an embodiment. According to some embodiments, the semiconductor package 300 of FIG. 3A may include one or more of the conductive slugs 320b and the IHSs 320 shown in FIGS. 3B-3D, where the conductive slugs 320b and the IHSs 320 may be implemented (or designed/formed) with several different shapes based on the desired packaging design, the desired thermal applications, and so on. In these embodiments, as described above, the conductive slugs 320b may be disposed in targeted regions (or portions) of the IHS 320 and disposed on one or more of the regions of the top surfaces of the dies 310a-c, where the conductive slugs 320b may be disposed/positioned over/on any of the regions of the top surfaces of the dies 310a-c such as a central region, a periphery region, a corner region, a plurality of periphery regions, and so on.

For example, as shown in FIG. 3B, the conductive slugs 320b may be disposed on the periphery regions of the top surfaces of the dies 310a and 310c, where such conductive slugs 320 may be parallel to each other and shaped as a line, a trace, or the like with sharp edges or rounded edges. Additionally, these conductive slugs 320b may extend laterally from one outer sidewall to the opposite outer sidewall of the respective dies 310a and 310c. For some embodiments, the length of these conductive slugs 320b may be approximately equal to or greater than the length of the respective dies 310a and 310c, while, in other embodiments, the length of one or more of these conductive slugs 320b may be less than the length of the respective dies 310a and 310c. Note that, in these embodiments, the respective periphery regions of the top surfaces of the dies 310a and 310c may be selectively targeted to address even more localized hotspots generated by the dies 310a and 310c (or the satellite dies), as the respective periphery regions of the dies 310a and 310c may be the regions that are located closest (or most proximate) to the respective outer sidewalls of the die 310b (or the main die).

Additionally, as shown in FIG. 3B, the conductive slug 320a may be disposed on the central region of the top surface of the die 310b, while one of the conductive slugs 320b may be disposed on the periphery region(s) of the top surface of the die 310b, and may fully (or partially) surround the conductive slug 320a. For example, as shown in FIG. 3B, this conductive slug 320b may be shaped as a picture frame (or the like) to fully surround the outer sidewalls of the conductive slug 320a. For some embodiments, the length of this conductive slug 320b (disposed over the die 310b) may be approximately equal to or greater than the length of the other conductive slugs 320b (disposed over the other respective dies 310a and 310c), while, in other embodiments, the length of this conductive slugs 320b may be less than the length of the other conductive slugs 320b.

Meanwhile, as also shown in FIG. 3B, the conductive slugs 320c may be disposed between the conductive slugs 320b. In particular, each of the conductive slugs 320c may be positioned between two of the dies 310a and 310c, where one conductive slug 320c may be disposed between the outer sidewalls of the dies 310a-b, and another conductive slug 320c may be disposed between the outer sidewalls of the dies 310b-c. In some embodiments, the length of the conductive slugs 320c may be approximately equal to or less than the length of the respective dies 310a and 310c, while, in other embodiments, the length of one or more of the conductive slugs 320c may be less than the length of the respective dies 310a and 310c.

Referring now to FIG. 3C, the conductive slugs 320b may be substantially similar to the conductive slugs 320b described above in FIG. 3B, with the exception that the conductive slugs 320b may be disposed on two periphery regions of the top surface of the die 310b, and that the conductive slugs 320 may be parallel to each other and shaped as a line, a trace, or the like with sharp edges or rounded edges. Additionally, these conductive slugs 320b may extend laterally from one outer sidewall to the opposite outer sidewall of the die 310b. The lengths of these conductive slugs 320b disposed on the die 310b may be approximately equal to or different from each other.

Additionally, as shown in FIG. 3D, the conductive slugs 320b may be substantially similar to the conductive slugs 320b described above in FIG. 3B, with the exception that the conductive slugs 320b may be a plurality of smaller conductive slugs with rounded (or sharp) edges that are selectively disposed on a plurality of periphery regions of the top surface of the die 310b. In these embodiments, the smaller conductive slugs 320b may be selectively positioned and spaced apart from each other by the one or more thermally conductive portions of the lid of the IHS 320. Accordingly, in some embodiments, these smaller conductive slugs 320b may be combined and shaped into a picture frame that surrounds one or more regions of the outer sidewalls of the conductive slug 320a.

Note that the semiconductor package 300 and the IHS 320 may include fewer or additional packaging components based on the desired packaging design.

Referring now to FIG. 4, a cross-sectional illustration of a semiconductor package 400 is shown, in accordance with an embodiment. In some embodiments, the semiconductor package 400 may be substantially similar to the semiconductor package 300 described above in FIG. 3A, with the exception that the TIM 440 (or the like) may be disposed between the top surfaces of the dies 410a-c and the bottom surfaces of the IHS 420 and the respective conductive slugs 420a-c.

Whereas the conductive slugs 320a-b shown in FIG. 3A are disposed directly on the dies 310a-c, the conductive slugs 420a-b shown in FIG. 4 are disposed directly on the TIM 440, and thus the TIM 440 shown in FIG. 4 may be disposed directly between the top surfaces of the dies 410a-c and the bottom surfaces of the respective conductive slugs 420a-b. As described above, in an embodiment, the TIM 440 may be comprised of a metallic TIM, a STIM, a PTIM, or the like. In these embodiments, the TIM 440 may be directly disposed on each of the top surfaces of the dies 410a-c, where the thicknesses of the respective TIMs 440 may be substantially equal to or different from each other. While, in other embodiments, the TIM 440 may be disposed on one (or two) of the dies 410a-c, and thus the TIM 440 may not be disposed on at least one of the other (or remaining) dies 410a-c, where these other dies 410a-c may be directly coupled to the respective conductive slugs 420a-b.

Additionally, the components of the semiconductor package 400 may be substantially similar to the components of the semiconductor package 300 described above in FIG. 3A. Accordingly, the IHS 420, the cavity 419, the conductive slugs 420a-c, the interfaces 430a-c, the dies 410a-c, the package substrate 402, the bridges 450a-b with electrical routings 451-452, and the sealant 432 may be substantially similar to the IHS 320, the cavity 319, the conductive slugs 320a-b, the interfaces 330a-c, the dies 310a-c, the package substrate 302, the bridges 350a-b with electrical routings 351-352, and the sealant 332 described above in FIG. 3A.

Note that the semiconductor package 400 may include fewer or additional packaging components based on the desired packaging design.

Referring now to FIG. 5, a cross-sectional illustration of a semiconductor package 500 is shown, in accordance with an embodiment. In some embodiments, the semiconductor package 500 may be substantially similar to the semiconductor package 100, 200, 300, and 400 described above in FIGS. 1, 2, 3A-3D, and 4, with the exception that the top dies 510a-b are respectively stacked on the bottom dies 521a-b, that the encapsulation layer 580 may surround the top dies 510a-b and be disposed over the bottom dies 521a-b, and that the die 511 may be disposed adjacent to the stack of top dies 510b and bottom die 521b.

In these embodiments, the components of the semiconductor package 500 may be substantially similar to the components of the semiconductor package 300 described above in FIG. 3A. Accordingly, the IHS 520, the cavity 519, the conductive slugs 520a-c, the interfaces 530a-c, the dies 510a-b and 511, the bridges 550a-b with electrical routings 551-552, and the package substrate 502 may be substantially similar to the IHS 320, the cavity 319, the conductive slugs 320a-c, the interfaces 330a-c, the dies 310a-c, the bridges 350a-b with electrical routings 351-352, and the package substrate 302 described above in FIG. 3A.

Additionally, as shown in FIG. 5, the conductive slugs 520a-b may be disposed over/on the top dies 510a-b, the die 511, and/or the encapsulation layer 580. Likewise, as also shown in FIG. 5, the conductive slugs 520c may be disposed on the encapsulation layer 580 and between the conductive slugs 520b, where the conductive slugs 520 may also be positioned above/over the respective bridges 550a-b. Note that, as stated above, the conductive slugs 520a-c and the IHS 520 may be implemented (or designed/shaped) to be similar to the conductive slugs 320a-c and the IHS 320 of FIG. 3A.

Additionally, in some embodiments, the bottom dies 521a-b may be disposed and coupled onto the top surface of the package substrate 502 with an adhesive layer 523 (or the like). In another embodiment, the die 511 may be disposed and coupled onto the top surface of the package substrate 502 with a plurality of solder balls 543 (or the like), where the die 511 may be positioned closely adjacent to the top dies 110a-b and bottom dies 121a-b. In these embodiments, the stack of top dies 510a-b and bottom dies 521a-b may be implemented as embedded chiplet dies (or the like) that are stacked on the respective base dies, while the die 511 may be implemented as a semiconductor die, a memory die (e.g., a HBM), and/or a stack of dies (e.g., a stack of HBM dies).

In some embodiments, the bottom dies 521a-b may include a plurality of interconnects 531 that couple the bridges 550a-b and the package substrate 502 to the respective top dies 510a-b. In these embodiments, the interconnects 531 may be through-silicon vias (TSVs), through-glass vias (TGVs), and/or the like. Additionally, as shown in FIG. 5, the top surfaces of the encapsulation layer 580 and the top dies 510a-b may be substantially coplanar to the top surface of the die 511.

Note that the semiconductor package 500 may include fewer or additional packaging components based on the desired packaging design.

Referring now to FIG. 6, a cross-sectional illustration of a semiconductor package 600 is shown, in accordance with an embodiment. For some embodiments, the semiconductor package 600 may be substantially similar to the semiconductor packages 100, 200, 300, 400, and 500 described above in FIGS. 1-2, 3A-3D, and 4-5, with the exception that the package substrate 602 may be disposed on and coupled to the substrate 601 with the solder balls 623, and that the heatsink 622 and the TIM 640 may be respectively disposed on the top surface of the IHS 620.

Additionally, in alternative embodiments, the semiconductor package 600 may omit both the IHS 620 and the TIM 640. That is, in these alternative embodiments, the conductive slugs 620a-c may be disposed directly into the heatsink 622, while maintaining the same configuration (i.e., the same shapes, materials, positions, and so on) over the respective dies 610a-c. Accordingly, in such alternative embodiments, the bottom surfaces of the heatsink 622 and conductive slugs 620a-c may be directly disposed on the top surfaces of the respective dies 610a-c—without having an IHS and a TIM positioned between the heatsink 622 and the dies 610a-c.

Likewise, the components of the semiconductor package 600 may be substantially similar to the components of the semiconductor package 300 described above in FIG. 3A. Accordingly, the heatsink 622, the TIM 640, IHS 620, the cavity 619, the conductive slugs 620a-c, the interfaces 630a-c, the dies 610a-c, the package substrate 602, the substrate 601, the solder balls 623, the bridges 650a-b with electrical routings 651-652, and the sealant 632 may be substantially similar to the IHS 320, the cavity 319, the conductive slugs 320a-b, the interfaces 330a-c, the dies 310a-c, the package substrate 302, the bridges 350a-b with electrical routings 351-352, and the sealant 332 described above in FIG. 3A.

Note that the semiconductor package 600 may include fewer or additional packaging components based on the desired packaging design.

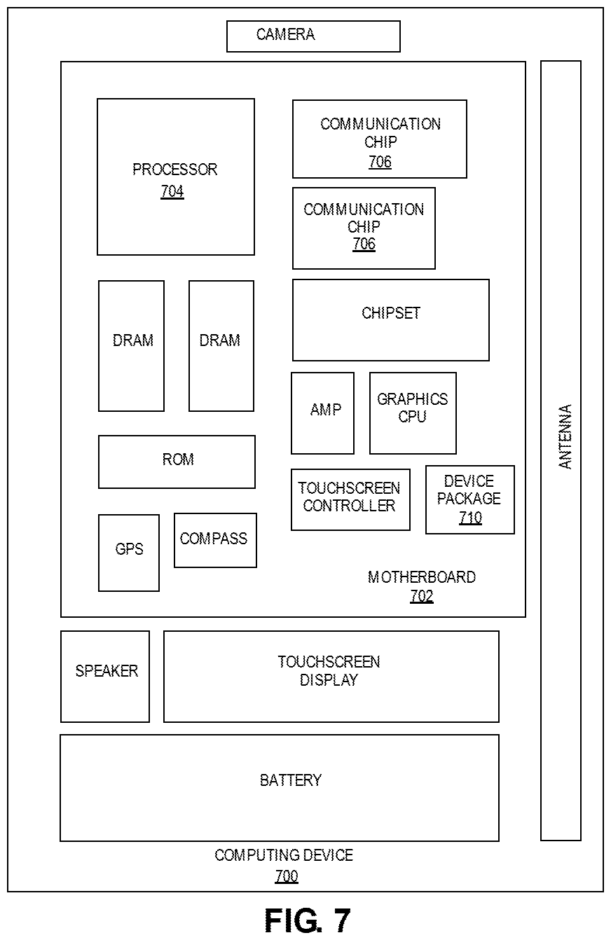

FIG. 7 is an illustration of a schematic block diagram illustrating a computer system 700 that utilizes a device package 710 (or a semiconductor package) with an IHS, a plurality of conductive slugs, a plurality of dies, and a package substrate, and a plurality of bridges, according to one embodiment. FIG. 7 illustrates an example of computing device 700. Computing device 700 houses a motherboard 702. Motherboard 702 may include a number of components, including but not limited to processor 704, device package 710 (or semiconductor package), and at least one communication chip 703. Processor 704 is physically and electrically coupled to motherboard 702. For some embodiments, at least one communication chip 706 is also physically and electrically coupled to motherboard 702. For other embodiments, at least one communication chip 706 is part of processor 704.

Depending on its applications, computing device 700 may include other components that may or may not be physically and electrically coupled to motherboard 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 706 enables wireless communications for the transfer of data to and from computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 706 may implement any of a number of wireless standards or protocols, including but not limited to Wi-Fi (IEEE 802.11 family), WiMAX (IEEE 802.112 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

Processor 704 of computing device 700 includes an integrated circuit die packaged within processor 704. Device package 710 may be a semiconductor package that may include, but is not limited to, a substrate, a package substrate, and/or a PCB. In one embodiment, device package 710 may be substantially similar to the semiconductor packages of FIGS. 1-6 described herein. Device package 710 may include the conductive slugs that are selectively positioned (or targeted) in the IHS and disposed on one or more regions of the top surfaces of the dies as described herein (e.g., as illustrated and described above with the conductive slugs and the IHS of FIGS. 1-6)—or any other components from the figures described herein.

Note that device package 710 may be a single component/device, a subset of components, and/or an entire system, as the materials, features, and components may be limited to device package 710 and/or any other component of the computing device 700 that may need the conductive slugs and IHSs as described herein (e.g., the motherboard 702, the processor 704, and/or any other component of the computing device 700 that may need the embodiments of the conductive slugs and IHSs, and the semiconductor packages described herein).

For certain embodiments, the integrated circuit die may be packaged with one or more devices on a package substrate that includes a thermally stable RFIC and antenna for use with wireless communications and the device package, as described herein, to reduce the z-height of the computing device. The term “processor” may refer to any device or portion of a device that processes electronic data from registers and/or memory to transform that electronic data into other electronic data that may be stored in registers and/or memory.

At least one communication chip 706 also includes an integrated circuit die packaged within the communication chip 706. For some embodiments, the integrated circuit die of the communication chip 706 may be packaged with one or more devices on a package substrate that includes one or more device packages, as described herein.

In the foregoing specification, embodiments have been described with reference to specific exemplary embodiments thereof. It should be borne in mind, however, that all of these and similar terms are to be associated with the appropriate physical quantities and are merely convenient labels applied to these quantities. It will be evident that various modifications may be made thereto without departing from the broader spirit and scope. The specification and drawings are, accordingly, to be regarded in an illustrative sense rather than a restrictive sense.

The following examples pertain to further embodiments. The various features of the different embodiments may be variously combined with some features included and others excluded to suit a variety of different applications.

The Following Examples Pertain to Further Embodiments:

Example 1 is a semiconductor package, comprising: a first die and a second die on a package substrate; an IHS over the first die, the second die, and the package substrate, wherein the IHS has a lid and a plurality of sidewalls; and a plurality of conductive slugs in the lid of the IHS, wherein the lid of the IHS has a bottom surface that is coplanar to bottom surfaces of the plurality of conductive slugs, wherein the plurality of conductive slugs are comprised of one or more high-k thermal conductive materials, and wherein the bottom surfaces of the plurality of conductive slugs are on a top surface of the first die and a top surface of the second die.

In example 2, the subject matter of example 1 can optionally include that the IHS is comprised of one or more thermal conductive materials, wherein the one or more thermal conductive materials of the IHS are comprised of aluminum, copper, copper-based metals, or alloys, and wherein the bottom surface of the lid of the IHS is directly on a region of the top surface of the first die.

In example 3, the subject matter of examples 1-2 can optionally include that the one or more high-k thermal conductive materials of the plurality of conductive slugs are comprised of cubic boron nitride, hexagonal boron nitride, graphite, carbon-based materials, diamonds, or diamond-based materials.

In example 4, the subject matter of examples 1-3 can optionally include that the one or more high-k thermal conductive materials of the plurality of conductive slugs have a thermal conductivity that is approximately equal to or greater than 400 W/mK.

In example 5, the subject matter of examples 1-4 can optionally include that the plurality of conductive slugs include a first conductive slug and a second conductive slug, wherein the first conductive slug has a width that is less than a width of the second conductive slug, wherein the second conductive slug has a thickness that is approximately equal to or less than a thickness of the first conductive slug, wherein the lid of the IHS directly surrounds a top surface and one or more outer sidewalls of the first conductive slug, and wherein the lid of the IHS directly surrounds a top surface and one or more outer sidewalls of the second conductive slug.

In example 6, the subject matter of examples 1-5 can optionally include that the first conductive slug has a bottom surface that is directly on a periphery region of the top surface of the first die, and wherein the top surface of the first die is coupled to the bottom surface of the first conductive slug and the bottom surface of the lid of the IHS.

In example 7, the subject matter of examples 1-6 can optionally include that the second conductive slug has a bottom surface that is directly on the top surface of the second die, and wherein the bottom surface of the second conductive slug has a footprint that is substantially equal to a footprint of the top surface of the second die.

In example 8, the subject matter of examples 1-7 can optionally include that the plurality of conductive slugs have one or more vertical sidewalls, tapered sidewalls, or rounded sidewalls, wherein the first conductive slug is comprised of the diamond-based materials, and wherein the second conductive slug is comprised of the cubic boron nitride or the hexagonal boron nitride.

In example 9, the subject matter of examples 1-8 can optionally include a TIM on at least the top surface of the first die or the top surface of the second die, wherein the TIM is disposed between the first die and the first conductive slug, or the second die and the second conductive slug; a bridge in the package substrate, wherein the bridge communicatively couples the first die to the second die; and a third conductive slug in the lid of the IHS, wherein the third conductive slug is directly between the first conductive slug and the second conductive slug, wherein the third conductive slug is directly positioned above the bridge, wherein the third conductive slug has a thickness that is less than the thicknesses of the first and second conductive slugs, wherein the third conductive slug has a bottom surface that is coplanar to the bottom surfaces of the lid of the IHS, the first conductive slug, and the second conductive slug, and wherein the third conductive slug is comprised of one or more low-k thermal conductive materials.

Example 10 is a semiconductor package, comprising: a first die and a second die on a package substrate; an IHS over the first die, the second die, and the package substrate, wherein the IHS has a lid and a plurality of sidewalls; a plurality of first conductive slugs in the lid of the IHS; and a second conductive slug in the lid of the IHS, wherein the lid of the IHS has a bottom surface that is coplanar to a bottom surface of the second conductive slug and bottom surfaces of the plurality of first conductive slugs, wherein the plurality of first conductive slugs and the second conductive slug are comprised of one or more high-k thermal conductive materials, wherein the bottom surfaces of the plurality of first conductive slugs are on a first region of a top surface of the first die and a first region of a top surface of the second die, and wherein the bottom surface of the second conductive slug is on a second region of the top surface of the second die.

In example 11, the subject matter of example 10 can optionally include that the IHS is comprised of one or more thermal conductive materials, wherein the one or more thermal conductive materials of the IHS are comprised of aluminum, copper, copper-based metals, or alloys, and wherein the bottom surface of the lid of the IHS is directly on a second region of the top surface of the first die.

In example 12, the subject matter of examples 10-11 can optionally include that the one or more high-k thermal conductive materials of the plurality of first conductive slugs and the second conductive slug are comprised of cubic boron nitride, hexagonal boron nitride, graphite, carbon-based materials, diamonds, or diamond-based materials.

In example 13, the subject matter of examples 10-12 can optionally include that the one or more high-k thermal conductive materials of the plurality of first conductive slugs and the second conductive slug have a thermal conductivity that is approximately equal to or greater than 400 W/mK.

In example 14, the subject matter of examples 10-13 can optionally include that the plurality of first conductive slugs include a first conductive slug and a third conductive slug, wherein the second conductive slug has a width that is greater than a width of the first conductive slug, wherein the first conductive slug has a thickness that is substantially equal to a thickness of the third conductive slug, wherein the second conductive slug has a thickness that is approximately equal to or less than the thicknesses of the first and third conductive slugs, wherein the lid of the IHS directly surrounds a top surface and one or more outer sidewalls of the first conductive slug, and wherein the lid of the IHS directly surrounds a top surface and one or more outer sidewalls of the third conductive slug.

In example 15, the subject matter of examples 10-14 can optionally include that the first conductive slug has a bottom surface that is directly on a periphery region of the top surface of the first die, and wherein the top surface of the first die is coupled to the bottom surface of the first conductive slug and the bottom surface of the lid of the IHS.

In example 16, the subject matter of examples 10-15 can optionally include that the second conductive slug has a bottom surface that is directly on a central region of the top surface of the second die, wherein the third conductive slug has a bottom surface that is directly on one or more periphery regions of the top surface of the second die, wherein the third conductive slug has one or more surfaces that are directly adjacent to one or more outer sidewalls of the second conductive slug, and wherein the lid of the IHS directly surrounds a top surface of the second conductive slug or one or more outer sidewalls of the second conductive slug.

In example 17, the subject matter of examples 10-16 can optionally include that the plurality of first conductive slugs and the second conductive slug have one or more vertical sidewalls, tapered sidewalls, or rounded sidewalls, wherein the plurality of first conductive slugs are comprised of the diamond-based materials, and wherein the second conductive slug is comprised of the cubic boron nitride or the hexagonal boron nitride.

In example 18, the subject matter of examples 10-17 can optionally include a TIM on at least the top surface of the first die or the top surface of the second die, wherein the TIM is disposed between the first die and the first conductive slug, or the second die and the second and third conductive slugs; a bridge in the package substrate, wherein the bridge communicatively couples the first die to the second die; and a fourth conductive slug in the lid of the IHS, wherein the fourth conductive slug is directly between the first conductive slug and the third conductive slug, wherein the fourth conductive slug is directly positioned above the bridge, wherein the fourth conductive slug has a thickness that is less than the thicknesses of the first, second, and third conductive slugs, wherein the fourth conductive slug has a bottom surface that is coplanar to the bottom surfaces of the lid of the IHS, the first conductive slug, the second conductive slug, and the third conductive slug, and wherein the fourth conductive slug is comprised of one or more low-k thermal conductive materials.

Example 19 is a semiconductor package, comprising: a first die, a second die, and a third die on a package substrate, wherein the second die is positioned between the first die and the third die; an IHS over the first die, the second die, the third die, and the package substrate, wherein the IHS has a lid and a plurality of sidewalls; a plurality of first conductive slugs and a second conductive slug in the lid of the IHS, wherein the plurality of first conductive slugs and the second conductive slug are comprised of one or more high-k thermal conductive materials, wherein the plurality of first conductive slugs have bottom surfaces that are on a first region of a top surface of the first die, a first region of a top surface of the second die, and a first region of a top surface of the third die, and wherein the second conductive slug has a bottom surface that is on a second region of the top surface of the second die; and a plurality of third conductive slugs in the lid of the IHS, wherein the lid of the IHS has a bottom surface that is coplanar to the bottom surfaces of the plurality of first conductive slugs, the second conductive slug, and the plurality of third conductive slugs, wherein the plurality of third conductive slugs have one or more outer sidewalls that are directly adjacent to one or more outer sidewalls of the plurality first conductive slugs, and wherein the plurality of third conductive slugs are comprised of one or more low-k thermal conductive materials.

In example 20, the subject matter of example 19 can optionally include that the IHS is comprised of one or more thermal conductive materials, wherein the one or more thermal conductive materials of the IHS are comprised of aluminum, copper, copper-based metals, or alloys, wherein the bottom surface of the lid of the IHS is directly on a second region of the top surface of the first die and a second region of the top surface of the third die, wherein the one or more high-k thermal conductive materials of the plurality of first conductive slugs and the second conductive slug are comprised of cubic boron nitride, hexagonal boron nitride, graphite, carbon-based materials, diamonds, or diamond-based materials, wherein the one or more high-k thermal conductive materials of the plurality of first conductive slugs and the second conductive slug have a thermal conductivity that is approximately equal to or greater than 400 W/mK, and wherein the one or more low-k thermal conductive materials of the plurality of third conductive slugs have a thermal conductivity that is approximately equal to or less than 30 W/mK.

In example 21, the subject matter of examples 19-20 can optionally include that the plurality of first conductive slugs include a first conductive slug, a fourth conductive slug, and a fifth conductive slug, wherein the second conductive slug has a width that is greater than a width of the first conductive slug and a width of the fifth conductive slug, wherein the first conductive slug has a thickness that is substantially equal to a thickness of the fourth conductive slug and a thickness of the fifth conductive slugs, wherein the second conductive slug has a thickness that is approximately equal to or less than the thicknesses of the first, fourth, and fifth conductive slugs, wherein the plurality of third conductive slugs have a thickness that is approximately equal to or less than the thicknesses of the first, second, fourth, and fifth conductive slugs, wherein the lid of the IHS directly surrounds a top surface and one or more outer sidewalls of the first conductive slug, wherein the lid of the IHS directly surrounds a top surface and one or more outer sidewalls of the fourth conductive slug, and wherein the lid of the IHS directly surrounds a top surface and one or more outer sidewalls of the fifth conductive slug.

In example 22, the subject matter of examples 19-21 can optionally include that the first conductive slug has a bottom surface that is directly on a periphery region of the top surface of the first die, wherein the fifth conductive slug has a bottom surface that is directly on a periphery region of the top surface of the third die, wherein the top surface of the first die is coupled to the bottom surface of the first conductive slug and the bottom surface of the lid of the IHS, and wherein the top surface of the third die is coupled to the bottom surface of the fifth conductive slug and the bottom surface of the lid of the IHS.

In example 23, the subject matter of examples 19-22 can optionally include that the second conductive slug has a bottom surface that is directly on a central region of the top surface of the second die, wherein the fourth conductive slug has a bottom surface that is directly on one or more periphery regions of the top surface of the second die, wherein the fourth conductive slug has one or more surfaces that are directly adjacent to one or more outer sidewalls of the second conductive slug, and wherein the lid of the IHS directly surrounds a top surface of the second conductive slug or one or more outer sidewalls of the second conductive slug.

In example 24, the subject matter of examples 19-23 can optionally include that the plurality of first conductive slugs, the second conductive slug, and the plurality of third conductive slugs have one or more vertical sidewalls, tapered sidewalls, or rounded sidewalls, wherein the plurality of first conductive slugs are comprised of the diamond-based materials, and wherein the second conductive slug is comprised of the cubic boron nitride or the hexagonal boron nitride.

In example 25, the subject matter of examples 19-24 can optionally include that a TIM on at least the top surface of the first die, the top surface of the second die, or the top surface of the third die, wherein the TIM is disposed between the first die and the first conductive slug, the second die and the second and fourth conductive slugs, or the third die and the fifth conductive slug; and a plurality of bridges in the package substrate, wherein the plurality of bridges communicatively couples the first, second, and third dies to each other, wherein the plurality of third conductive slugs are directly positioned above the plurality of bridges, wherein one of the plurality of third conductive slugs is positioned between the first conductive slug and the fourth conductive slug, and wherein another of the plurality of third conductive slugs is positioned between the fifth conductive slug and the fourth conductive slug.

In the foregoing specification, methods and apparatuses have been described with reference to specific exemplary embodiments thereof. It will be evident that various modifications may be made thereto without departing from the broader spirit and scope. The specification and drawings are, accordingly, to be regarded in an illustrative sense rather than a restrictive sense.

What is claimed is:

1. A semiconductor package, comprising:
a first die and a second die on a package substrate;
an integrated heat spreader (IHS) over the first die, the second die, and the package substrate, wherein the IHS has a lid and a plurality of sidewalls; and
a plurality of conductive slugs in the lid of the IHS, wherein the lid of the IHS has a bottom surface that is coplanar to bottom surfaces of the plurality of conductive slugs, wherein the plurality of conductive slugs are comprised of one or more high-k thermal conductive materials, and wherein the bottom surfaces of the plurality of conductive slugs are on a top surface of the first die and a top surface of the second die.

2. The semiconductor package of claim 1, wherein the IHS is comprised of one or more thermal conductive materials, wherein the one or more thermal conductive materials of the IHS are comprised of aluminum, copper, copper-based metals, or alloys, and wherein the bottom surface of the lid of the IHS is directly on a region of the top surface of the first die.

3. The semiconductor package of claim 1, wherein the one or more high-k thermal conductive materials of the plurality of conductive slugs are comprised of cubic boron nitride, hexagonal boron nitride, graphite, carbon-based materials, diamonds, or diamond-based materials.

4. The semiconductor package of claim 3, wherein the one or more high-k thermal conductive materials of the plurality of conductive slugs have a thermal conductivity that is approximately equal to or greater than 400 W/mK.

5. The semiconductor package of claim 3, wherein the plurality of conductive slugs include a first conductive slug and a second conductive slug, wherein the first conductive slug has a width that is less than a width of the second conductive slug, wherein the second conductive slug has a thickness that is approximately equal to or less than a thickness of the first conductive slug, wherein the lid of the IHS directly surrounds a top surface and one or more outer sidewalls of the first conductive slug, and wherein the lid of the IHS directly surrounds a top surface and one or more outer sidewalls of the second conductive slug.

6. The semiconductor package of claim 5, wherein the first conductive slug has a bottom surface that is directly on a periphery region of the top surface of the first die, and wherein the top surface of the first die is coupled to the bottom surface of the first conductive slug and the bottom surface of the lid of the IHS.

7. The semiconductor package of claim 5, wherein the second conductive slug has a bottom surface that is directly on the top surface of the second die, and wherein the bottom surface of the second conductive slug has a footprint that is substantially equal to a footprint of the top surface of the second die.

8. The semiconductor package of claim 5, wherein the plurality of conductive slugs have one or more vertical sidewalls, tapered sidewalls, or rounded sidewalls, wherein the first conductive slug is comprised of the diamond-based materials, and wherein the second conductive slug is comprised of the cubic boron nitride or the hexagonal boron nitride.

9. The semiconductor package of claim 5, further comprising:
a thermal interface material (TIM) on at least the top surface of the first die or the top surface of the second die, wherein the TIM is disposed between the first die and the first conductive slug, or the second die and the second conductive slug;
a bridge in the package substrate, wherein the bridge communicatively couples the first die to the second die; and
a third conductive slug in the lid of the IHS, wherein the third conductive slug is directly between the first conductive slug and the second conductive slug, wherein the third conductive slug is directly positioned above the bridge, wherein the third conductive slug has a thickness that is less than the thicknesses of the first and second conductive slugs, wherein the third conductive slug has a bottom surface that is coplanar to the bottom surfaces of the lid of the IHS, the first conductive slug, and the second conductive slug, and wherein the third conductive slug is comprised of one or more low-k thermal conductive materials.

10. A semiconductor package, comprising:
a first die and a second die on a package substrate;
an integrated heat spreader (IHS) over the first die, the second die, and the package substrate, wherein the IHS has a lid and a plurality of sidewalls;
a plurality of first conductive slugs in the lid of the IHS; and
a second conductive slug in the lid of the IHS, wherein the lid of the IHS has a bottom surface that is coplanar to a bottom surface of the second conductive slug and bottom surfaces of the plurality of first conductive slugs, wherein the plurality of first conductive slugs and the second conductive slug are comprised of one or more high-k thermal conductive materials, wherein the bottom surfaces of the plurality of first conductive slugs are on a first region of a top surface of the first die and a first region of a top surface of the second die, and wherein the bottom surface of the second conductive slug is on a second region of the top surface of the second die.

11. The semiconductor package of claim 10, wherein the IHS is comprised of one or more thermal conductive materials, wherein the one or more thermal conductive materials of the IHS are comprised of aluminum, copper, copper-based metals, or alloys, and wherein the bottom surface of the lid of the IHS is directly on a second region of the top surface of the first die.

12. The semiconductor package of claim 10, wherein the one or more high-k thermal conductive materials of the plurality of first conductive slugs and the second conductive slug are comprised of cubic boron nitride, hexagonal boron nitride, graphite, carbon-based materials, diamonds, or diamond-based materials.

13. The semiconductor package of claim 12, wherein the one or more high-k thermal conductive materials of the plurality of first conductive slugs and the second conductive slug have a thermal conductivity that is approximately equal to or greater than 400 W/mK.

14. The semiconductor package of claim 12, wherein the plurality of first conductive slugs include a first conductive slug and a third conductive slug, wherein the second conductive slug has a width that is greater than a width of the first conductive slug, wherein the first conductive slug has a thickness that is substantially equal to a thickness of the third conductive slug, wherein the second conductive slug has a thickness that is approximately equal to or less than the thicknesses of the first and third conductive slugs, wherein the lid of the IHS directly surrounds a top surface and one or more outer sidewalls of the first conductive slug, and wherein the lid of the IHS directly surrounds a top surface and one or more outer sidewalls of the third conductive slug.

15. The semiconductor package of claim 14, wherein the first conductive slug has a bottom surface that is directly on a periphery region of the top surface of the first die, and wherein the top surface of the first die is coupled to the bottom surface of the first conductive slug and the bottom surface of the lid of the IHS.

16. The semiconductor package of claim 14, wherein the second conductive slug has a bottom surface that is directly on a central region of the top surface of the second die, wherein the third conductive slug has a bottom surface that is directly on one or more periphery regions of the top surface of the second die, wherein the third conductive slug has one or more surfaces that are directly adjacent to one or more outer sidewalls of the second conductive slug, and wherein the lid of the IHS directly surrounds a top surface of the second conductive slug or one or more outer sidewalls of the second conductive slug.

17. The semiconductor package of claim 12, wherein the plurality of first conductive slugs and the second conductive slug have one or more vertical sidewalls, tapered sidewalls, or rounded sidewalls, wherein the plurality of first conductive slugs are comprised of the diamond-based materials, and wherein the second conductive slug is comprised of the cubic boron nitride or the hexagonal boron nitride.

18. The semiconductor package of claim 14, further comprising:
a thermal interface material (TIM) on at least the top surface of the first die or the top surface of the second die, wherein the TIM is disposed between the first die and the first conductive slug, or the second die and the second and third conductive slugs;
a bridge in the package substrate, wherein the bridge communicatively couples the first die to the second die; and
a fourth conductive slug in the lid of the IHS, wherein the fourth conductive slug is directly between the first conductive slug and the third conductive slug, wherein the fourth conductive slug is directly positioned above the bridge, wherein the fourth conductive slug has a thickness that is less than the thicknesses of the first, second, and third conductive slugs, wherein the fourth conductive slug has a bottom surface that is coplanar to the bottom surfaces of the lid of the IHS, the first conductive slug, the second conductive slug, and the third conductive slug, and wherein the fourth conductive slug is comprised of one or more low-k thermal conductive materials.

19. A semiconductor package, comprising:
a first die, a second die, and a third die on a package substrate, wherein the second die is positioned between the first die and the third die;
an integrated heat spreader (IHS) over the first die, the second die, the third die, and the package substrate, wherein the IHS has a lid and a plurality of sidewalls;
a plurality of first conductive slugs and a second conductive slug in the lid of the IHS, wherein the plurality of first conductive slugs and the second conductive slug are comprised of one or more high-k thermal conductive materials, wherein the plurality of first conductive slugs have bottom surfaces that are on a first region of a top surface of the first die, a first region of a top surface of the second die, and a first region of a top surface of the third die, and wherein the second conductive slug has a bottom surface that is on a second region of the top surface of the second die; and
a plurality of third conductive slugs in the lid of the IHS, wherein the lid of the IHS has a bottom surface that is coplanar to the bottom surfaces of the plurality of first conductive slugs, the second conductive slug, and the plurality of third conductive slugs, wherein the plurality of third conductive slugs have one or more outer sidewalls that are directly adjacent to one or more outer sidewalls of the plurality first conductive slugs, and wherein the plurality of third conductive slugs are comprised of one or more low-k thermal conductive materials.

20. The semiconductor package of claim 19, wherein the IHS is comprised of one or more thermal conductive materials, wherein the one or more thermal conductive materials of the IHS are comprised of aluminum, copper, copper-based metals, or alloys, wherein the bottom surface of the lid of the IHS is directly on a second region of the top surface of the first die and a second region of the top surface of the third die, wherein the one or more high-k thermal conductive materials of the plurality of first conductive slugs and the second conductive slug are comprised of cubic boron nitride, hexagonal boron nitride, graphite, carbon-based materials, diamonds, or diamond-based materials, wherein the one or more high-k thermal conductive materials of the plurality of first conductive slugs and the second conductive slug have a thermal conductivity that is approximately equal to or greater than 400 W/mK, and wherein the one or more low-k thermal conductive materials of the plurality of third conductive slugs have a thermal conductivity that is approximately equal to or less than 30 W/mK.

21. The semiconductor package of claim 19, wherein the plurality of first conductive slugs include a first conductive slug, a fourth conductive slug, and a fifth conductive slug, wherein the second conductive slug has a width that is greater than a width of the first conductive slug and a width of the fifth conductive slug, wherein the first conductive slug has a thickness that is substantially equal to a thickness of the fourth conductive slug and a thickness of the fifth conductive slugs, wherein the second conductive slug has a thickness that is approximately equal to or less than the thicknesses of the first, fourth, and fifth conductive slugs, wherein the plurality of third conductive slugs have a thickness that is approximately equal to or less than the thicknesses of the first, second, fourth, and fifth conductive slugs, wherein the lid of the IHS directly surrounds a top surface and one or more outer sidewalls of the first conductive slug, wherein the lid of the IHS directly surrounds a top surface and one or more outer sidewalls of the fourth conductive slug, and wherein the lid of the IHS directly surrounds a top surface and one or more outer sidewalls of the fifth conductive slug.

22. The semiconductor package of claim 21, wherein the first conductive slug has a bottom surface that is directly on a periphery region of the top surface of the first die, wherein the fifth conductive slug has a bottom surface that is directly on a periphery region of the top surface of the third die, wherein the top surface of the first die is coupled to the bottom surface of the first conductive slug and the bottom surface of the lid of the IHS, and wherein the top surface of the third die is coupled to the bottom surface of the fifth conductive slug and the bottom surface of the lid of the IHS.

23. The semiconductor package of claim 21, wherein the second conductive slug has a bottom surface that is directly on a central region of the top surface of the second die, wherein the fourth conductive slug has a bottom surface that is directly on one or more periphery regions of the top surface of the second die, wherein the fourth conductive slug has one or more surfaces that are directly adjacent to one or more outer sidewalls of the second conductive slug, and wherein the lid of the IHS directly surrounds a top surface of the second conductive slug or one or more outer sidewalls of the second conductive slug.

24. The semiconductor package of claim 20, wherein the plurality of first conductive slugs, the second conductive slug, and the plurality of third conductive slugs have one or more vertical sidewalls, tapered sidewalls, or rounded sidewalls, wherein the plurality of first conductive slugs are comprised of the diamond-based materials, and wherein the second conductive slug is comprised of the cubic boron nitride or the hexagonal boron nitride.

25. The semiconductor package of claim 21, further comprising:
a thermal interface material (TIM) on at least the top surface of the first die, the top surface of the second die, or the top surface of the third die, wherein the TIM is disposed between the first die and the first conductive slug, the second die and the second and fourth conductive slugs, or the third die and the fifth conductive slug; and
a plurality of bridges in the package substrate, wherein the plurality of bridges communicatively couples the first, second, and third dies to each other, wherein the plurality of third conductive slugs are directly positioned above the plurality of bridges, wherein one of the plurality of third conductive slugs is positioned between the first conductive slug and the fourth conductive slug, and wherein another of the plurality of third conductive slugs is positioned between the fifth conductive slug and the fourth conductive slug.
